(19) United States
(12) Patent Application Publication
(10) Pub. No.: US 2009/0072269 A1
(43) Pub. Date: Mar. 19, 2009

(54) GALLIUM NITRIDE DIODES AND INTEGRATED COMPONENTS

(76) Inventors: Chang Soo Suh, Goleta, CA (US); James Honea, Santa Barbara, CA (US); Umesh Mishra, Montecito, CA (US)

Correspondence Address: FISH & RICHARDSON P.C., PO BOX 1022, MINNEAPOLIS, MN, 55440-1022, US

(21) Appl. No.: 11/856,695

(22) Filed: Sep. 17, 2007

(51) Int. Cl. H01L 29/423

(52) U.S. Cl. 257/136; 257/E29.123

(57) ABSTRACT

A diode device can include an enhancement mode gallium nitride transistor having a gate, a drain and a source, wherein the gate is connected to the drain to enable the device to perform as a diode. In some embodiments, an integrated switching-diode is described that includes a substrate, a gallium nitride switching transistor on the substrate and a free wheeling diode on the substrate and coupled to the switching transistor.

### CROSS REFERENCE TO RELATED APPLICATIONS

This application is related to co-pending U.S. application Ser. No. 11/856,687, filed on Sep. 17, 2007, which is incorporated herein for all purposes.

### BACKGROUND

This disclosure is related to gallium nitride based semiconductor transistors.

Gallium nitride (GaN) semiconductor devices, which are III-V type devices, are emerging as an attractive candidate for power semiconductor devices because the GaN devices are capable of carrying large currents and supporting high voltages. Such devices are also able to provide very low on resistance and fast switching times. A high electron mobility transistor (HEMT) is one type power semiconductor device that can be fabricated based on GaN materials. As used herein, GaN materials that are suitable for transistors can include secondary, tertiary, or quaternary materials, which are based on varying the amounts of the III type material of AlInGaN, Al, In and Ga, from 0 to 1, or AlₓIn_{y}Ga_{1-x-y}N, where x+y=1. Further, GaN materials can include various polarities of GaN, such as Ga-polar, N-polar, semi-polar or non-polar. N-face material may be obtained from N-polar or semi-polar GaN.

A GaN HEMT device can include a III-nitride semiconductor body with at least two III-nitride layers formed thereon. Different materials formed on the body or a on buffer layer causes the layers to have different band gaps. The different materials in the adjacent III-nitride layers also causes polarization, which contributes to a conductive, two-dimensional electron gas (2DEG) region near the junction of the two layers, specifically in the layer with the narrower band gap. The device also includes a schottky electrode, i.e., a gate, forming a first contact and an ohmic source and drain electrodes on either side of the gate. The region between the gate and drain and the gate and source, which allows current to be conducted through the device, is the access region.

Integrated components used in power circuits often include a combination of transistors and diodes. For example, a transistor with an anti-parallel (or fly-back) diode may be used. Because of the potential usefulness of GaN devices in power devices, improved GaN devices and integrated components are desirable.

### SUMMARY

Gallium nitride devices for power electronics are described.

In some embodiments, a diode device is described that includes an enhancement mode gallium nitride transistor having a gate, a drain and a source, wherein the gate is connected to the drain to enable the device to perform as a diode.

In some embodiments, an integrated switching transistor-diode device is described. The device includes a substrate, a gallium nitride switching transistor on the substrate and a free wheeling diode on the substrate coupled to the switching transistor.

In some embodiments, a multi-use integrated gallium nitride device is described. The device includes a first transistor and a second transistor together supplied as a five terminal device and field plates. The first transistor and second transistors are gallium nitride transistors that operate in the enhancement mode. The field plate for the first transistor is offset toward an end terminal of the first transistor and the field plate for the second transistor is offset toward an end terminal of the second transistor.

In some embodiments, an integrated switching-diode device is described. The device includes an enhancement mode gallium nitride switching transistor, a free wheeling diode and a field plate. The free wheeling diode is coupled to the switching transistor, wherein the free wheeling diode is a transistor with a reverse blocking voltage of at least 600V and a forward voltage drop below 3V, and has a gate connected to a drain. The field plate is electrically connected to the gate and offset towards the source.

Implementations of the devices described herein can include one or more of the following features. The device can be a lateral power device. The gate can be closer to the drain than to the source. A field plate can be electrically connected to the gate. The field plate can extend toward the source. The field plate can be directly connected to the gate within an active area of the device. The field plate can be isolated from the gate inside an active area of the device. The threshold voltage of the transistor can be +1V. The transistor has a reverse blocking voltage of at least 600 V, such as at least 900 V or at least 1200 V. The forward voltage drop can be between 0.5 and 3V. The forward voltage drop can be less than 3V. The internal barrier can be more than 0.5 eV. The free wheeling diode can be coupled to the transistor to provide a shunt path across the transistor. The transistor can be an enhancement mode transistor. The diode can be a transistor including a gate, a source and a drain and the gate is connected to the drain. The gate can be closer to the drain than to the source. A field plate can be electrically connected to the gate. The field plate can extend toward the source. Within an active area of the gate-drain connected transistor, the field plate can be directly electrically connected to the gate. Within an active area of the gate-drain connected transistor, the field plate can be isolated from the gate. The diode can be a schottky diode. The diode can be a metal-insulator-semiconductor diode. The diode can be a p-n junction diode. The device can be a lateral power device. The transistor can be a power switching transistor.

Embodiments of the devices described herein may provide one or more of the following advantages. The turn-on voltage of the diode or the threshold voltage of the transistor or device may be tunable. A diode may be formed with a lower turn on voltage and a lower reverse leakage current than in conventional diodes. If an enhancement mode device is used, additional negative bias is not required to turn the device off at 0 drain-gate voltage. The internal barrier of the diode, which provides the forward voltage, can be adjusted to maximize the on-current to the off-current ratio. That is, the reverse and forward performance of the diode can be simultaneously optimized.

Multiple components may be formed on a single substrate, resulting in a device with a compact layout and a reduced semiconductor area. Thus, smaller components can be created. A device with few components can be formed. The transistor can be a lateral device, which can be easier to integrate with and connect to other components. Because the gate-drain connection can easily be made, the connection need not be external to the chip at the package level. A more planar type of module packaging topology may also be achieved.

The configurations and methods described herein can result in devices with low loss and fast speeds. They can be less expensive to produce than conventional devices. Further, they can be suitable for use with high voltage power devices.

The details of one or more embodiments of the invention are set forth in the accompanying drawings and the description below. Other features, objects, and advantages of the invention will be apparent from the description and drawings, and from the claims.

### DESCRIPTION OF DRAWINGS

FIG. 1 is a symbolic representation of a gate-drain connected transistor that functions as a diode.

FIG. 2 is a schematic plan view of a gate-drain connected transistor.

FIG. 3 is a schematic cross-sectional view of a transistor.

FIGS. 4-7 are band diagrams under the gate regions of HEMT GaN transistors for various transistor structures, also schematically shown.

FIG. 8 is a schematic plan view of a gate-drain connected transistor with a field plate.

FIGS. 9 and 10 are schematic cross sectional views of a transistor with a field plate.

FIG. 11 is a symbolic representation of a transistor connected to a diode.

FIG. 12 is a symbolic representation of a transistor connected to a gate-drain connected transistor, which acts as a diode.

FIG. 13 is a schematic plan view of an integrated power-switch and free-wheeling diode device.

FIG. 14 is symbolic representation of a transistor connected to a diode.

FIG. 15 is a schematic plan view of a device with transistors connected to diodes.

FIG. 16 is a symbolic representation of an integrated device.

FIG. 17 is a symbolic representation of a configurable device.

FIGS. 18-26 schematically show the steps of forming an exemplary III-nitride device.

Like reference symbols in the various drawings indicate like elements.

### DETAILED DESCRIPTION

Power switching transistors typically use an anti-parallel diode (also referred to as the free-wheeling diode or a snubber diode) when in power circuits. When the power transistor switch turns off, a large fly-back voltage is generated by the inductive load. The role of the freewheeling diode is to clamp the fly-back voltage by turning on and conducting current. This prevents damage to the transistor and to the overall circuit. Diodes and integrated power switching transistors and diodes can be formed of GaN materials, as described further herein.

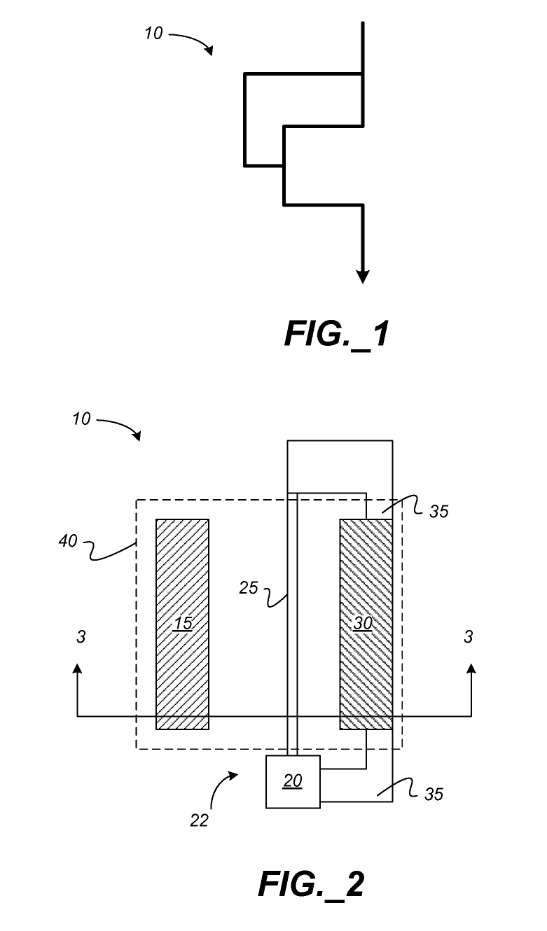

Referring to FIGS. 1-3, a gate-drain connected enhancement mode or normally off transistor 10 functions as a fast switching diode, such as schottky type fast switching diodes. The transistor 10 is a GaN based field effect transistor (FET) that includes a source 15 and a drain 30, both within an active area 40 of the transistor 10. In some embodiments the active area 40 includes the region in which the source 15 and drain 30 are located, but does not extend laterally beyond the region in which the source 15 and drain 30 are located. A gate pad 20 is electrically connected to the drain 30 by a first portion of connector 35 and by gate finger 25, which is in turn electrically connected to a second portion of connector 35. The source 15, drain 20, gate finger 25, gate pad 20 (gate finger 25 and gate pad 20 together as gate structure 22) and connector 35 are formed on active semiconductor material 55, which in turn is on substrate 50. In some embodiments, only the gate finger 25 is directly electrically connected to the drain 30 by the connector 35. In other embodiments, only the gate pad 20 is directly electrically connected to the drain 30 by the connector 35. Isolation areas 60 isolate the active semiconductor material 55 from other components on the substrate. In some embodiments, isolation areas 60 consist of implant isolations or mesa isolations, where area 60 is removed.

As shown, in FIG. 2, the gate structure 22 and drain 30 are connected outside of the active area 40 of the device. In alternative embodiments, the gate-drain connection can be within the active area 40 of the device or both within and outside of the active area 40 of the device, as device topology allows.

Connecting the gate and drain allows the transistor to function as a diode, which can act as a free-wheeling diode when appropriately connected across another transistor. In the gate-drain connected device 10, the threshold voltage of the underlying transistor is essentially the turn-on voltage of the diode. When the gate voltage V_{g} and drain voltage V_{d} are below the threshold voltage Vₜ of the device, (V_{g}=V_{d})<Vₜ, the device is off. Any voltage up to the breakdown voltage of the gate-source region V_{gs} of the original transistor is then blocked. At (V_{g}=V_{d})>Vₜ, the transistor in effect operates as a diode, because the gate and drain are forced to be at the same voltage (V_{g}=V_{d}) and the current increases exponentially near threshold and with a power law versus the applied voltage thereafter.

In some embodiments, the transistor is a GaN enhancement mode or normally off transistor. An enhancement mode transistor can be useful in power electronics because it is not desirable to have a high voltage device turned on when there is no bias applied at the gate. The forward voltage of the diode can be tuned by varying the threshold voltage of the enhancement mode device. The transistors described herein are power transistors, which are capable of blocking at least 600 V, such as at least 900 V or at least 1200 V. GaN provides a high breakdown voltage wide-bandgap semiconductor diode. In an integrated component of a gate-drain connected transistor-diode and with an additional transistor functioning as a regular power transistor switch, the threshold voltage of the gate-drain connected transistor-diode in combination with the component's on resistance determines the forward voltage of the diode. The threshold voltage of the diode can independently be optimized from the threshold voltage of the other transistor.

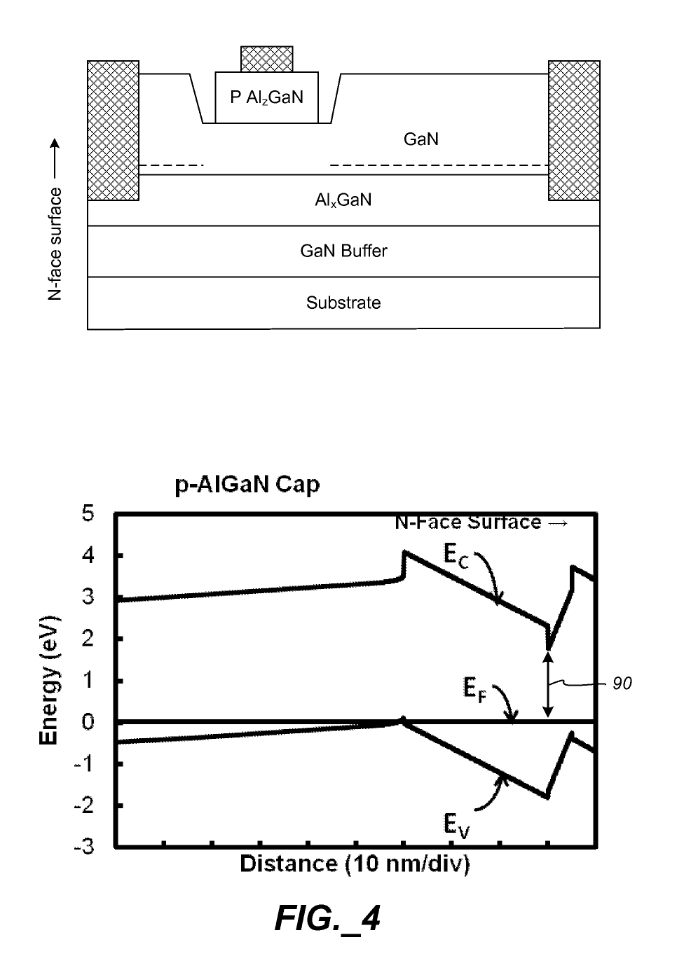

Referring to FIGS. 4-7, enhancement mode GaN transistors, or normally off GaN transistors, can be formed in a number of ways and are described further in co-pending application U.S. Ser. No. 11/856,687, filed Sep. 17, 2007, which is incorporated by reference herein for all purposes. The band diagrams of the HEMT GaN devices under the gate show the conduction band (E_{C}) and valence band (E_{V}) with respect to the Fermi level (E_{F}). In the band diagram, the minimum distance 90 between the conductance band E_{C} and the Fermi level E_{F} with no connection made to the gate indicates the device's internal barrier.

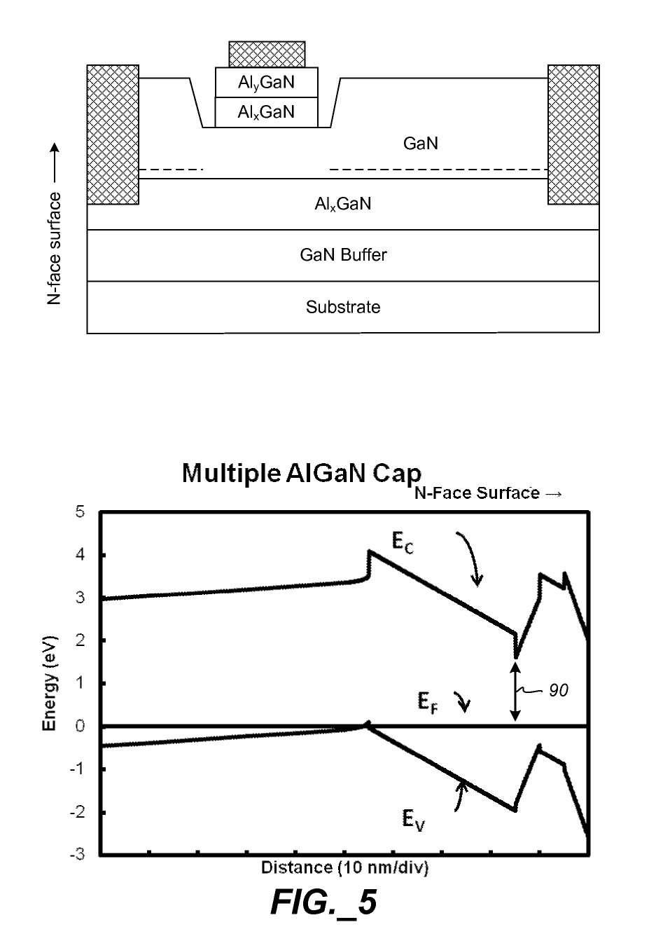

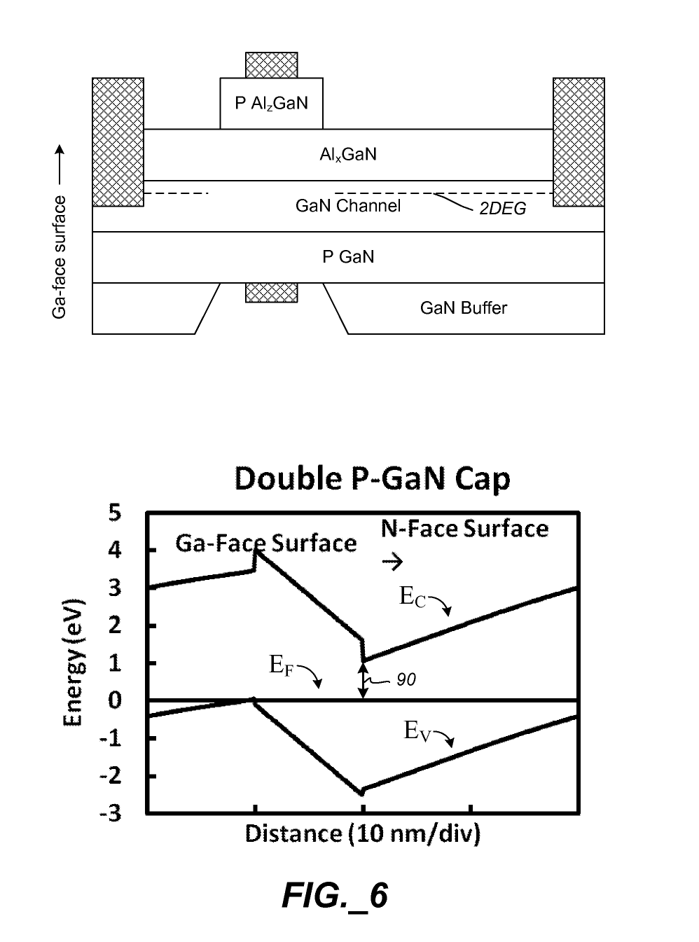

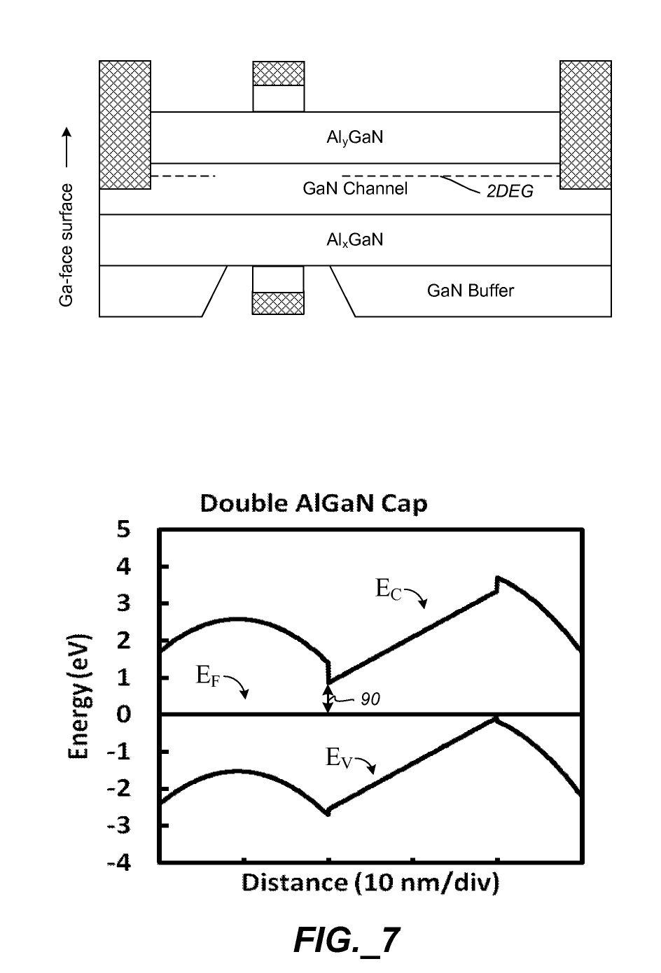

Referring to FIG. 4, a p-type AlGaN cap can be formed on an N-face device between the gate and 2DEG region to result in a device with an internal barrier of greater than 1.5 eV under the gate region. This provides for a normally off device with a reduced off state leakage. Referring to FIG. 5, a multilayer AlGaN cap can be formed on an N-face device between the gate and 2DEG to result in a device with an internal barrier of greater than 1.4 eV. Referring to FIG. 6, a device with an exposed p-type GaN layer on an opposite side of the device from the gate and a p-type AlₓGaN cap can result in a device with an internal barrier of greater than 0.9 eV. Referring to FIG. 7, a device that has been treated with fluorine plasma under the gate and in a region of an exposed AlₓGaN layer on an opposite side of the device from, and corresponding to a lateral location of the gate, can result in a device with an internal barrier of greater than 0.8 eV. In each of the FIGS. 4-7, in the region where the conduction band E_{C} nears the Fermi energy E_{F}, minimum energy difference 90, determines the internal barrier for the device.

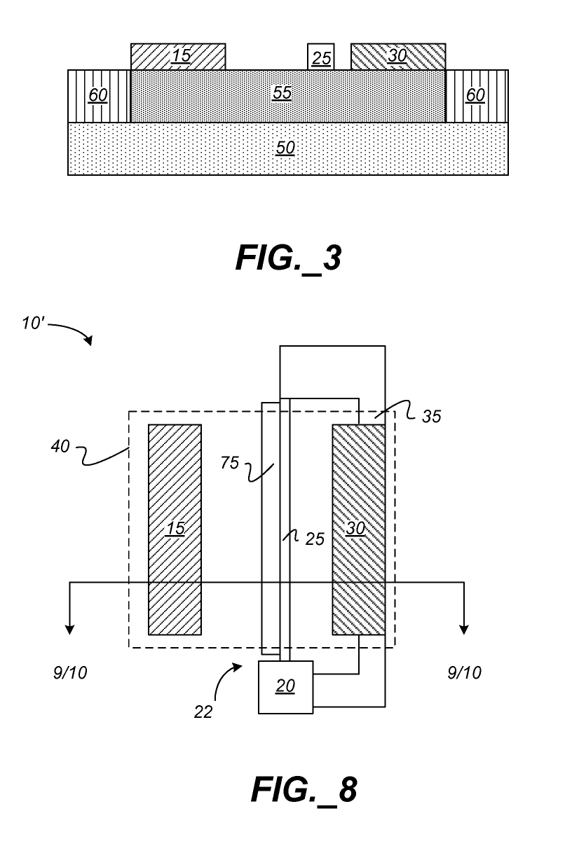

Referring back to FIGS. 2-3, in some embodiments, the gate structure 22 is positioned closer to the drain 30 than the source 15. In conventional transistors the gate structure 22 is typically closer to the source 15 than the drain 30. However, in a device in which the gate-drain connected transistor is used as a diode, the effective gate-drain voltage is zero and the gate structure 22 is offset toward the drain 30. Increasing the gate-source spacing allows the device, which acts as a diode, to block high reverse voltages.

Referring to FIG. 8, in some embodiments, a gate-drain connected transistor 10′ includes a field plate 75. The field plate 75 used with a GaN transistor can enhance the properties of the transistor, such as by reducing dc-rf dispersion and increasing breakdown voltages. The field plate 75 extends primarily towards the source 15, because the region between the gate and drain does not need to block voltage and the gate-source region is subject to higher electric fields, i.e., while withstanding the reverse voltage of the diode. This is contrary to the method of forming field plates in a standard transistor mode, where transistor field plates are substantially offset towards the drain side with small, if any, overlap on the source side. In some embodiments, one lateral edge of the field plate 75 is closer to the source 15 than an opposite lateral edge of the field plate 75 is to the drain 30. In some embodiments, the total extent of the field plate from the edge of the gate to the edge of the field plate on the source side is greater than the extent of the field plate from the opposite edge of the gate on the drain side of the gate. For example, if the source-gate spacing is 10 microns, the gate-drain spacing is 2 microns and the field plate extends 3 microns from the edge of the gate towards the source side, the field plate is geometrically closer to the drain but the area of the device that is field plated is 3 microns in the gate-source region and less, or none in the gate-drain region. That is, the portion of the field plate that does not overlap the gate is greater on the source side of the gate than on the drain side of the gate. In some embodiments, the field plate is at least 0.5 microns from the edge of the gate towards the source, such as between about 2 and 5 microns. In some embodiments, the field plate 75 is not merely offset, but the full field plate is towards the source.

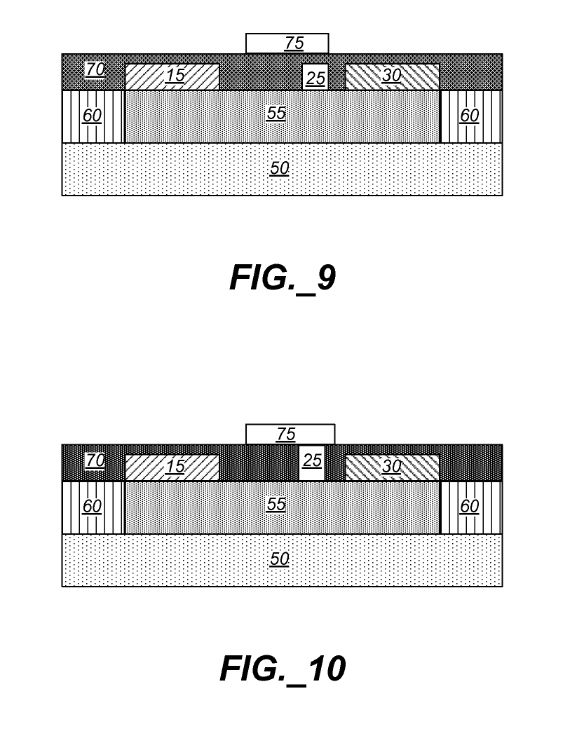

Referring to FIG. 9, in some embodiments, the field plate 75 is deposited on a dielectric spacer layer and is not in direct contact with the gate finger 25 within the active area 40 of the device. Rather, an insulator layer 70 covers the source 15, gate structure 22 and drain 30. The insulator can be a silicon nitride material or other suitable insulator material compatible with GaN devices. The field plate 75 is near the gate finger 25 and overlaps the gate finger 25, but the insulator layer 70 electrically isolates the field plate 75 from the gate structure 22 within the active area 40. Thus, the connection between the field plate 75 and the gate structure 22 is external to the active area 40 of the device. Referring to FIG. 10, in alternative embodiments, the field plate is integral to the gate. That is, the gate structure 22, or gate finger 25, is in direct electrical contact with the field plate 75 within the active area 40. In some embodiments, the field plate 75 extends laterally past the edge of the gate finger 25 towards both the source 15 and the drain 30.

In any device where the gate structure is in direct contact with the field plate 75 inside of, outside of or both inside and outside of the active area as in FIG. 9 or FIG. 10, the gate and drain are on the same side of the substrate 50 and thus the device is a lateral device. This allows for a connection between the gate and drain that is on one side of the device, rather than needing a connection that wraps around the device or using via holes made through the substrate. Specifically, because the device is a lateral device, the gate-drain connection can be made within the chip, rather than external to the chip packaging, as can be required in lateral devices.

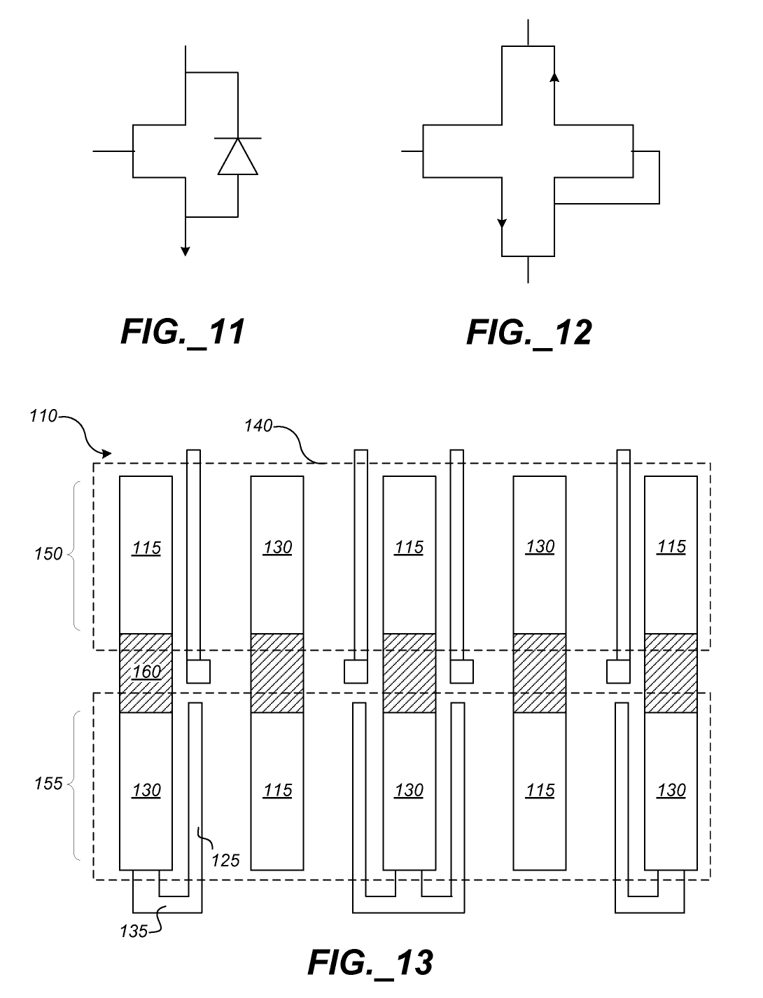

Referring the FIG. 11, a GaN based power transistor without the gate connected to the drain can be used in an integrated or monolithic device, which includes the GaN transistor in connection with a diode, such as a free wheeling diode based on GaN materials, e.g., a p-n junction diode or a schottky diode. The transistor and diode are both formed on the same substrate. Because the transistor and diode are on the same substrate, compact power switching modules can be formed. The gate-drain connected transistor described herein can also be used as the diode portion of the device in integrated components, such as the one schematically represented in FIG. 12. Here, the gate-drain connected transistor replaces the GaN diode of FIG. 11.

The unit cell of a transistor or diode represented in FIGS. 2 and 3 can be replicated and used in an integrated device. Referring to FIG. 13, an integrated power switch and free-wheeling diode device 110 includes one or more sets of unit cells including a switching transistor 150 and antiparallel or free-wheeling diode 155. Each diode 155 has a gate finger 125 connected to a drain 130 by an electrical connection 135. The source 115 of each switching transistor 150 is electrically connected to a drain 130 of a diode 155 by a diode-transistor connection bus 160 or by a dielectrically supported bridge. Similarly, each drain 130 of each switching transistor 150 is electrically connected to a source of a diode 155. In some embodiments, such as in a device with multiple diodes and multiple transistors, the sources of each diode unit cell are connected together and the drains of each diode unit cell are connected together, such as by a bridge or interlayer metallization layer. In these or other embodiments, all of the gate fingers 125 of the diodes 155 are electrically connected together.

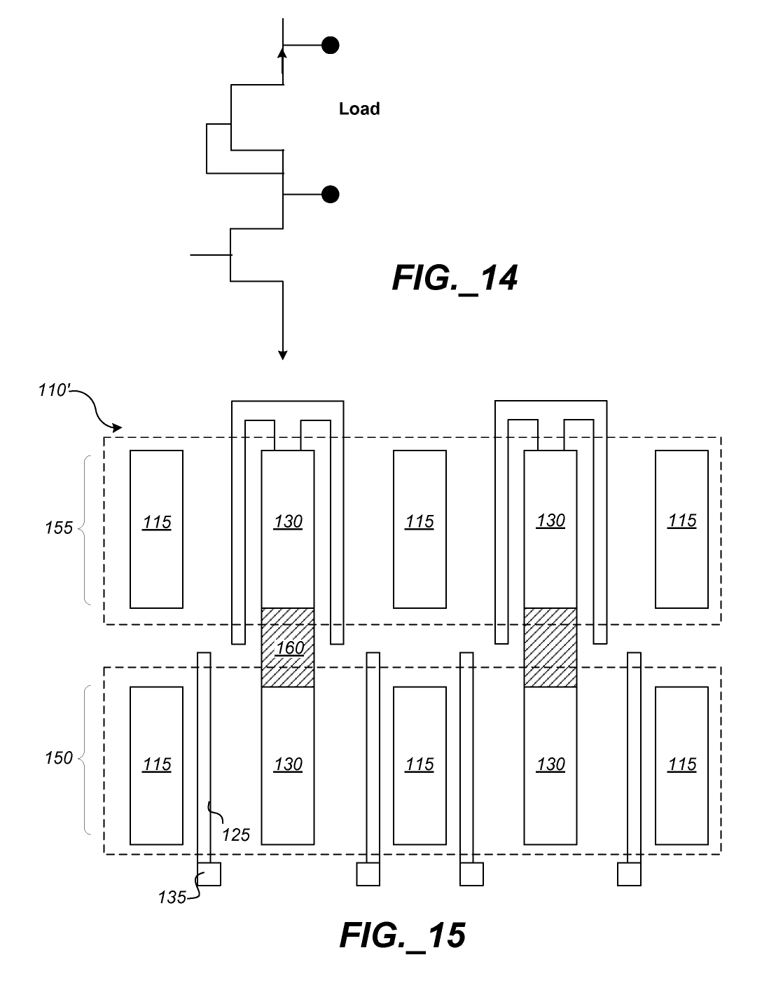

Referring to FIGS. 14 and 15, the integrated GaN based device including a switching transistor and a gate-drain connected transistor, which acts as a diode, can use the diode to shunt a load. In some embodiments, individual sources, drains and/or gates in the same device are connected by a bridge or an interlayer metallization. For example, all the sources 115 in the switching transistor 150 can be connected together and a single source contact of the switching transistor 150 can be used to contact the transistor device. All the drains 130 of the switching transistor can be connected together to form one terminal for the load. Similarly, all the sources 130 of the diode can be connected to form a second terminal for the load. The spacing and geometry of both the switching transistor 150 and diode 155 can be varied as needed based on the required voltage, frequency, current and other ratings.

In certain embodiments, an enhancement mode transistor has one or more of the following features, a +2V threshold voltage, either a 600 V or 1200 V reverse blocking capability, an average current rating of 10A-50A, a current density of about 10-500 mA/mm and an on resistance of <10 mohm-cm². The gate-drain connected enhancement mode transistor is able to withstand the same reverse voltage as the transistor, but the current capability varies between about 20% and 100% of the transistor current. In some embodiments, the diode is operable at FET equivalent current density of about 10-300 mA/mm. In some embodiments, the diode exhibits a forward voltage drop of about 0.5-3 V.

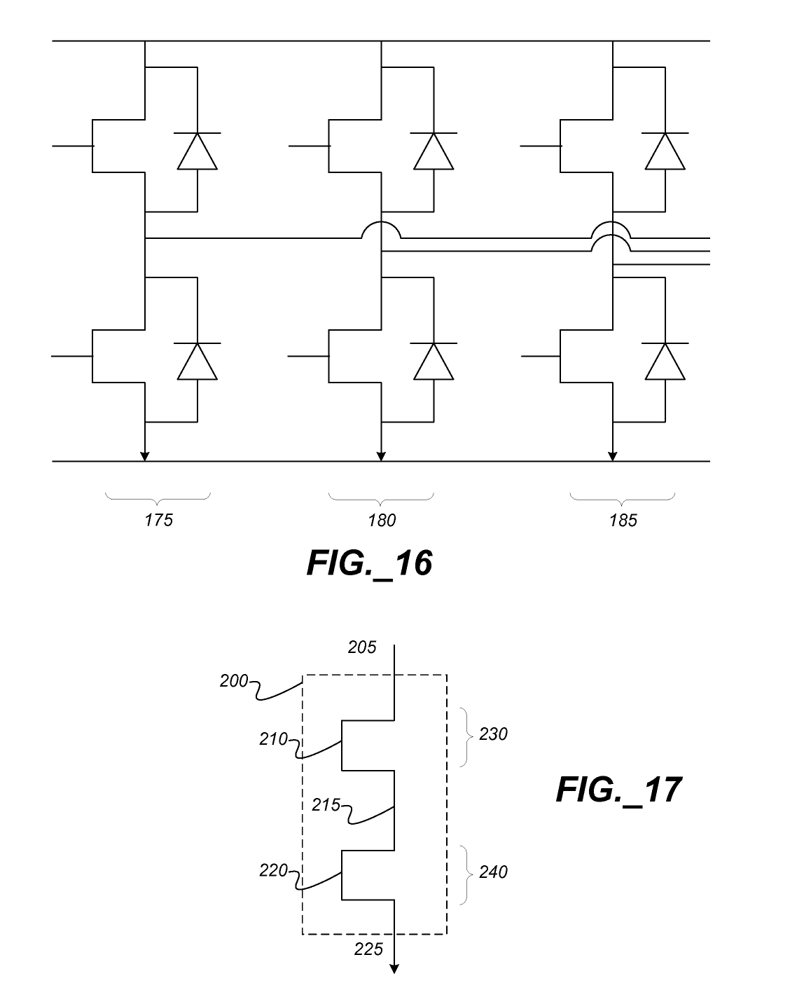

The power switching components and their integration can be applied to a variety of power electronic circuits, including but not limited to building blocks, such as a half bridge, full bridge, buck/boost/synchronous power converters/inverters and motor drives. For example, a schematic of a typical 3-phase AC motor drive is shown in FIG. 16, with a half-bridge configuration 175, 180, 185 for each phase. The switching transistor and the integrated free-wheeling diodes described herein can be used in pairs to form a half bridge. In some embodiments, all six components, i.e., the six transistors and six diodes, can be integrated in a single chip, such as after providing for adequate isolation between the devices. Specifically, the transistor and diode are formed on a single substrate to form a monolithic device. In some embodiments, some small percent of the current of a device can be tapped off, such as 1%, to measure the current of the device, acting as a current sense.

Referring to FIG. 17, a half bridge made up of two GaN transistors 230, 240 provides a configurable device 200. The half bridge is a 5-terminal 205, 210, 215, 220, 225 device. In one configuration, the half bridge is used as a half bridge component, e.g., as one phase of the 3-phase application of FIG. 16. Diodes can separately be connected or integrated with the half bridge. By connecting external terminals 210 and 215, this part of the device 200 functions a secondary side switch, such as in FIG. 13. This is because one of the transistors 230 becomes the gate-drain connected diode, i.e., terminal 215 acts as the drain connected to the gate at terminal 210. If terminals 210 and 215 are left unconnected, terminal 215 is the source of the transistor 230 and drain of transistor 240 as in a half bridge. In some embodiments, a field plate (not shown) is offset towards terminal 205 for the transistor 230 and towards terminal 215 for the transistor 240.

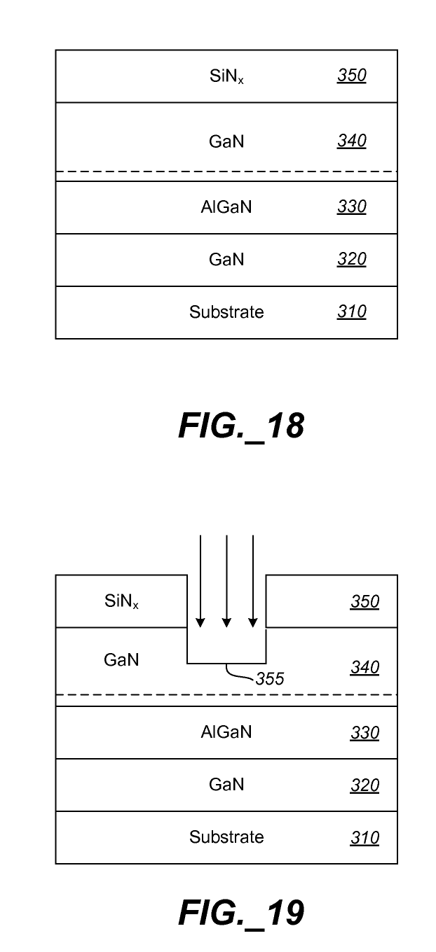

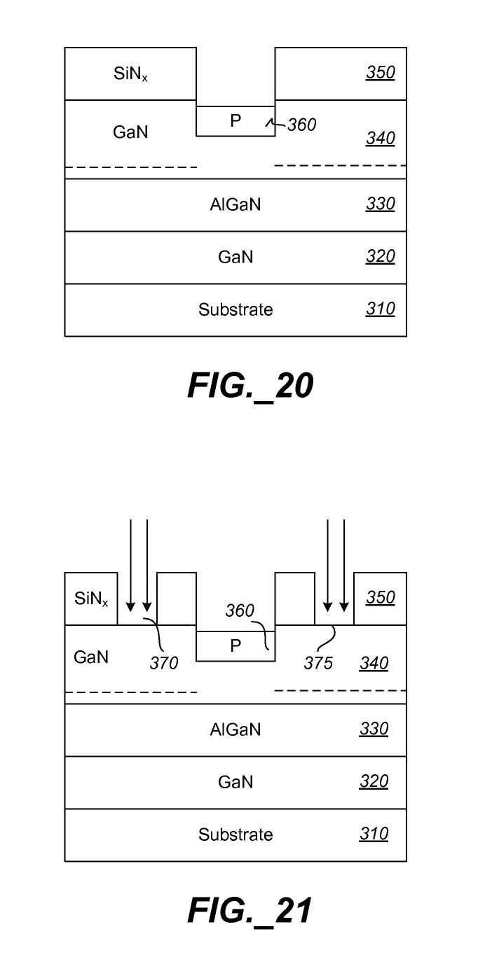

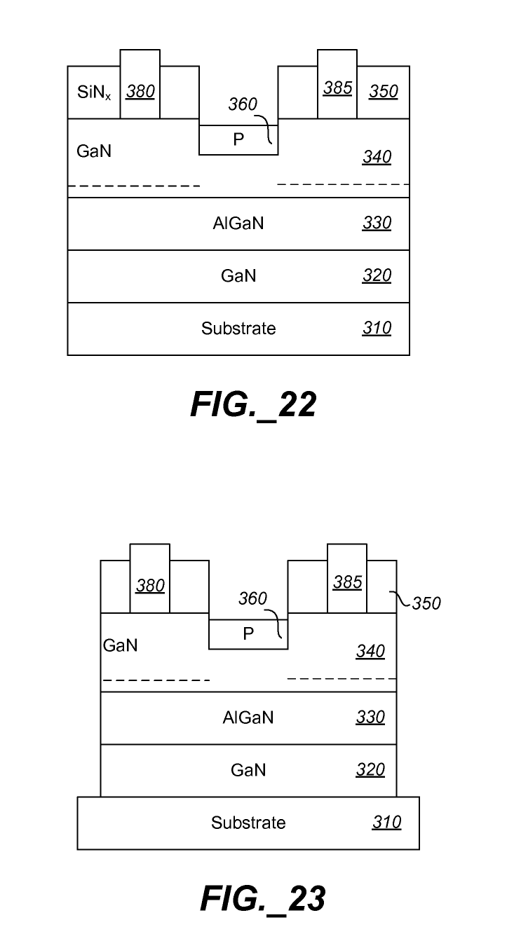

Referring to FIGS. 18-26, an exemplary method of forming a III-nitride device is described. Referring to FIG. 18, layers of GaN 320, AlGaN 330, GaN 340 and SiNₓ 350 are epitaxially grown on a substrate 310. In some embodiments, SiNₓ 350 is deposited after the epitaxial growth of the semiconductor layer is completed, rather than itself being grown epitaxially. The layer of SiNₓ 350 functions as a capping layer. Referring to FIG. 19, the layer of SiNₓ 350 and the layer of GaN 340 are etched to define a gate region 355. Referring to FIG. 20, a layer of p-type AlGaN 360 is selectively grown into the gate region 355, or regrown, as commonly described. The layer of SiNₓ 350 acts as a mask during the growth step. In some embodiments, an alternative suitable mask material is used. Referring to FIG. 21, the layer of SiNₓ 350 is again etched to open up source and drain contact regions 370, 375. Referring to FIG. 22, ohmic contacts are deposited into the contact regions 370, 375 to form source 380 and drain 385. The contacts can be formed of a Ti/Al/Ni/Au based metallization. Referring to FIG. 23, a single device is isolated from neighboring devices by mesa isolation, that is, by removing portions of the layers of GaN 320, AlGaN 330, GaN 340 and SiNₓ 350 from around the device region, which contains the source 380, drain 385 and gate region 355. Alternatively, implant isolation is used, where portions outside the active area of the device or region to be isolated are implanted with suitable ions rendering them highly resistive.

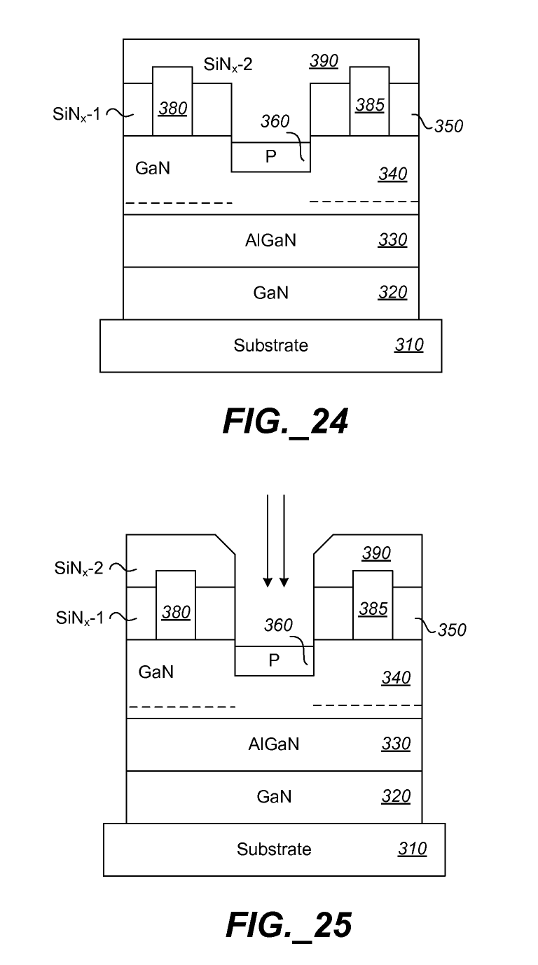

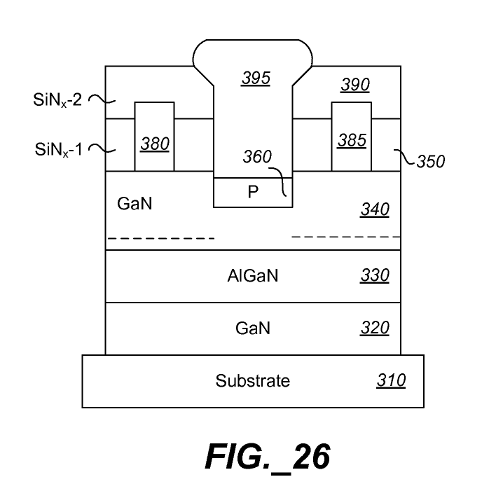

Referring to FIG. 24, a second layer of SiNₓ 390 is deposited onto the layer of SiNₓ 350. Layers 390 and 350 can be formed of the same type of SiNₓ or can be different types of SiNₓ materials. The layers can have the same or different thicknesses and can be deposited using the same or different techniques. Referring to FIG. 25, the SiNₓ layers 350, 390 are etched in the gate region. In some embodiments, the upper portion of the etched region has a slanted side wall. Referring to FIG. 26, a gate metal, such as Ni/Au based metallization, is then deposited to form gate 395. Other III-nitride materials, methods and geometries can be used in lieu of those described above to achieve similar devices.

Using GaN HEMT as a diode provides an independent parameter to control the forward voltage and reverse current. In a conventional diode, a low forward voltage results in a high reverse current, because the barrier that determines the forward voltage, also dictates the reverse current. Similarly, if a diode is designed for low reverse current it also exhibits high forward voltage. Because the gate-drain connected transistor is a three terminal device, parameters can be controlled that reduce the forward voltage drop and the reverse current leakage. The turn-on voltage of the transistor or device may be tunable. A diode may be formed with a combination of lower turn-on voltage and lower reverse leakage current than in conventional diodes. If an enhancement mode device is used, additional negative bias is not required to turn the device off at 0V drain-gate voltage. The internal barrier of the diode, along with the gate length of the transistor, which influences electric field, can be adjusted to maximize the on-current to the off-current ratio. That is, the reverse and forward performance of the diode can be simultaneously optimized.

Multiple GaN based components may be formed on a single substrate, resulting in a device with a compact layout and a reduced semiconductor area. Thus, smaller components can be created. A device with few components can be formed. The transistor can be a lateral device, which can be easier to integrate and connect to other components. Because the gate-drain connection can easily be made, the connection need not be external to the chip at the package level. A more planar type of module packaging topology may also be achieved.

A number of embodiments of the invention have been described. Nevertheless, it will be understood that various modifications may be made without departing from the spirit and scope of the invention. Accordingly, other embodiments are within the scope of the following claims.

What is claimed is:

1. A diode device, comprising:
an enhancement mode gallium nitride transistor having a gate, a drain and a source, wherein the gate is connected to the drain to enable the device to perform as a diode.

2. The diode device of claim 1, wherein the device is a lateral power device.

3. The diode device of claim 1, wherein the gate is closer to the drain than to the source.

4. The diode device of claim 3, further comprising a field plate electrically connected to the gate.

5. The diode device of claim 4, wherein the field plate extends toward the source.

6. The diode device of claim 4, wherein the field plate is directly connected to the gate within an active area of the device.

7. The diode device of claim 4, wherein the field plate is isolated from the gate inside an active area of the device.

8. The diode device of claim 1, wherein the transistor has a reverse blocking voltage of at least 600 V.

9. The diode device of claim 1, wherein the transistor has a reverse blocking voltage of at least 1200 V.

10. The diode device of claim 1, wherein the forward voltage drop is between 0.5 and 3V.

11. The diode device of claim 1, wherein the internal barrier is more than 0.5 eV.

12. An integrated switching transistor-diode device, comprising:
a substrate;
a gallium nitride switching transistor on the substrate; and
a free wheeling diode on the substrate coupled to the switching transistor.

13. The device of claim 12, wherein the transistor is an enhancement mode transistor.

14. The device of claim 12, wherein the diode is a transistor including a gate, a source and a drain and the gate is connected to the drain.

15. The device of claim 14, wherein the gate is closer to the drain than to the source.

16. The device of claim 15, further comprising a field plate electrically connected to the gate.

17. The device of claim 16, wherein the field plate extends toward the source.

18. The device of claim 16, wherein within an active area of the gate-drain connected transistor, the field plate is directly electrically connected to the gate.

19. The device of claim 16, wherein within an active area of the gate-drain connected transistor, the field plate is isolated from the gate.

20. The device of claim 12, wherein the diode is a schottky diode.

21. The device of claim 12, wherein the diode is a metal-insulator-semiconductor diode.

22. The device of claim 12, wherein the diode is a p-n junction diode.

23. The device of claim 12, wherein the device is a lateral power device.

24. A multi-use integrated gallium nitride device, comprising:
a first transistor and a second transistor together supplied as a five terminal device, wherein the first transistor and second transistors are gallium nitride transistors that operate in the enhancement mode; and
a field plate for the first transistor offset toward an end terminal of the first transistor, and a field plate for the second transistor offset toward an end terminal of the second transistor.

25. An integrated switching-diode device, comprising:
an enhancement mode gallium nitride switching transistor;
a free wheeling diode coupled to the switching transistor, wherein the free wheeling diode is a transistor with a reverse blocking voltage of at least 600V and a forward voltage drop below 3V, and having a gate connected to a drain; and
a field plate electrically connected to the gate and offset towards the source.
